(19) United States
(12) Patent Application Publication
(10) Pub. No.: US 2025/0374724 A1
(43) Pub. Date: Dec. 4, 2025

(54) DISPLAY PANEL PACKAGE

(71) Applicant: CHIPBOND TECHNOLOGY CORPORATION, Hsinchu (TW)

(72) Inventor: Kuei-Hao Pang, Kaohsiung City (TW)

(21) Appl. No.: 18/790,024

(22) Filed: Jul. 31, 2024

(30) Foreign Application Priority Data
Jun. 4, 2024 (TW) 113120715

(51) Int. Cl. H01L 33/62; H01L 25/075

(52) U.S. Cl. CPC H10H 20/857; H01L 25/0753

(57) ABSTRACT

A display panel package includes a carrier, light-emitting elements and a chip, the light-emitting elements are mounted on the carrier, and the chip is mounted on a portion to be bent of the carrier. The chip includes bumps each having at least one composite contact. The composite contact includes a bonding layer and a base which is covered by the bonding layer to form a nonplanar surface on each of the bumps. The bonding layer located on the nonplanar surface is bonded to a pad of the carrier to increase bonding area of the bump and the pad and improve bonding strength between the carrier and the chip.

### CROSS-REFERENCE TO RELATED APPLICATIONS

This application claims priority to R.O.C patent application No. 113120715 filed Jun. 4, 2024, the disclosure of which is hereby incorporated by reference in its entirety.

### FIELD OF THE INVENTION

This invention relates to a display panel package, and more particularly to a flexible display panel package with a chip mounted on a portion to be bent of a carrier.

### BACKGROUND OF THE INVENTION

In order to conform to curve requirement of electronic product (e.g. digital signage), display panels need to be bent. With reference to FIGS. 1 and 2, a conventional display panel 10 includes a carrier 11, light-emitting elements 12 and a chip 13 which is bonded to pads 11a on the carrier 11 via bumps 13a. If the chip 13 is mounted on the bend of the bent display panel 10, shear stress may generate on the bumps 13a or the intermetallic interface between the pads 11a and the bumps 13a due to the chip 13 cannot be bent with the carrier 11. As a result, crack or break may be observed on the bumps 13a or the intermetallic interface. While the chip 13 is mounted on the inner bending surface as shown in FIG. 1, the bumps 13a located middle of the chip 13 may peel from the pads 11a resulted from shear stress. On the other hand, while the chip 13 is mounted on the outer bending surface as shown in FIG. 2, shear stress may cause the bumps 13a located on outer area of the chip 13 peel from the pads 11a and cause open circuit between the pads 11a and the bumps 13a or signal transmission error.

### SUMMARY OF THE INVENTION

One object of the present invention is to provide a display panel package with improved bonding strength between a carrier and a chip mounted on a bent portion of the carrier.

A display panel package of the present invention includes a carrier, light-emitting elements and a chip. The carrier includes first and second pads, the light-emitting elements are mounted on the carrier and electrically connected to the first pads, and the chip is mounted on a portion to be bent of the carrier. The chip includes chip pads and bumps, each of the bumps has a composite contact which includes a base and a bonding layer. The bonding layer is electrically connected to the chip pads and covers the base such that each of the bumps has a nonplanar surface. The bonding layer located on the nonplanar surface is bonded to the second pads.

The composite contact has the base and the bonding layer covering the base so a nonplanar surface is formed on each of the bumps. And the bumps are bonded to the second pads through the nonplanar surface of the composite contact to increase bonding area of the bumps and the second pads and further improve bonding strength between the carrier and the chip mounted on the portion to be bent. Consequently, crack or break on the bumps or intermetallic interface between the bumps and the second pads will not be observed, and the bumps will not peel from the second pads to cause open circuit.

### BRIEF DESCRIPTION OF DRAWINGS

FIG. 1 is a cross-section view diagram illustrating a conventional display panel.

FIG. 2 is a cross-section view diagram illustrating a conventional display panel.

FIG. 3 is a cross-section view diagram illustrating a display panel package in accordance with a first embodiment of the present invention.

FIG. 4 is a cross-section view diagram illustrating a display panel package in accordance with a second embodiment of the present invention.

FIG. 5 is a cross-section view diagram illustrating a display panel package in accordance with a third embodiment of the present invention.

FIGS. 6A to 6C are bottom view diagrams illustrating a chip in accordance with the first embodiment of the present invention.

FIGS. 7A to 7C are bottom view diagrams illustrating a chip in accordance with the second embodiment of the present invention.

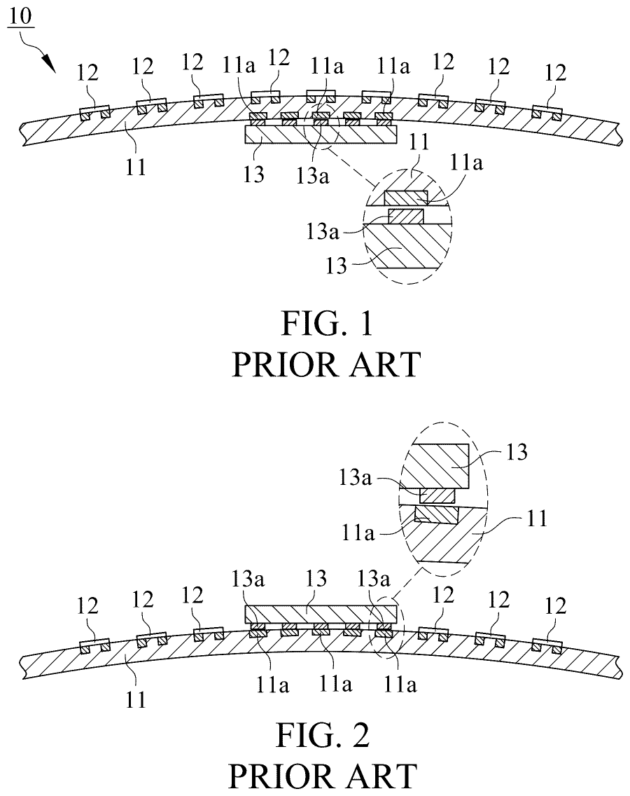

### DETAILED DESCRIPTION OF THE INVENTION

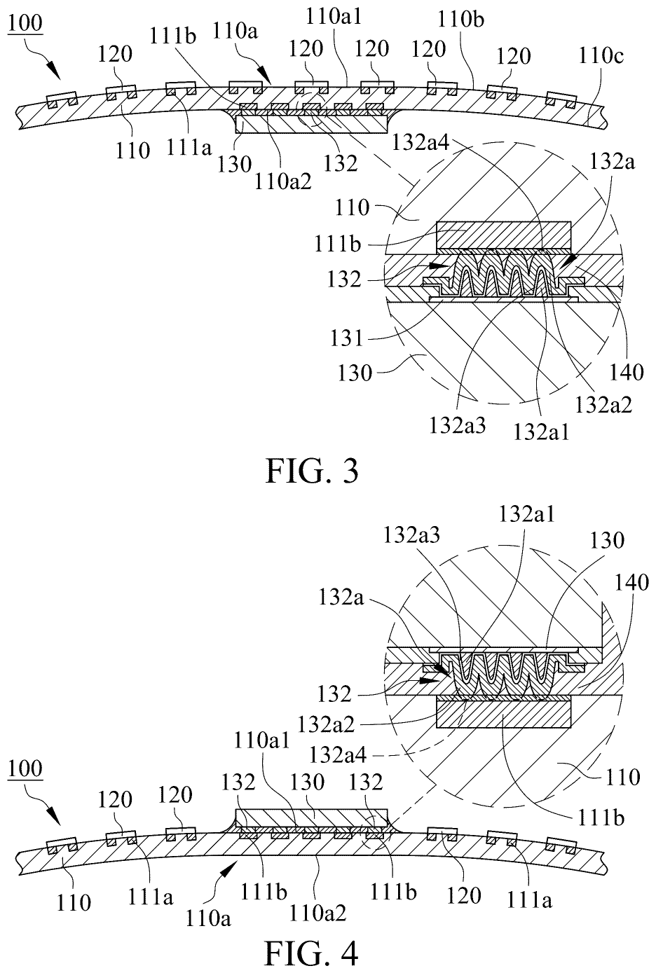

With reference to FIGS. 3 and 4, a display panel package 100 includes a carrier 110, light-emitting elements 120 and at least one chip 130. The light-emitting elements 120 are, but not limited to, light-emitting diodes (LED), and the chip 130 is, but not limited to, a driver IC. The light-emitting elements 120 and the chip 130 are mounted on different surfaces of the carrier 110 in a first embodiment as shown in FIG. 3, and they are mounted on the same surface of the carrier 110 in a second embodiment as shown in FIG. 4.

With reference to FIGS. 3 and 4, the carrier 110 includes first pads 111a and second pads 111b, the light-emitting elements 120 are mounted on the carrier 110 and electrically connected to the first pads 111a, and the chip 130 is mounted on a portion 110a to be bent of the carrier 110 and electrically connected to the second pads 111b. The portion 110a to be bent has an outer bending surface 110a1 and an inner bending surface 110a2 opposite to each other, the chip 130 of the first embodiment is mounted on the inner bending surface 110a2 and the chip 130 of the second embodiment is mounted on the outer bending surface 110a1.

The carrier 110 has a first surface 110b and a second surface 110c. In the first embodiment as shown in FIG. 3, the first pads 111a are arranged on and visible from the first surface 110b and the second pads 111b are arranged on and visible from the second surface 111c. And in the second embodiment as shown in FIG. 4, the first pads 111a and the second pads 111b are arranged on and visible from the first surface 110b.

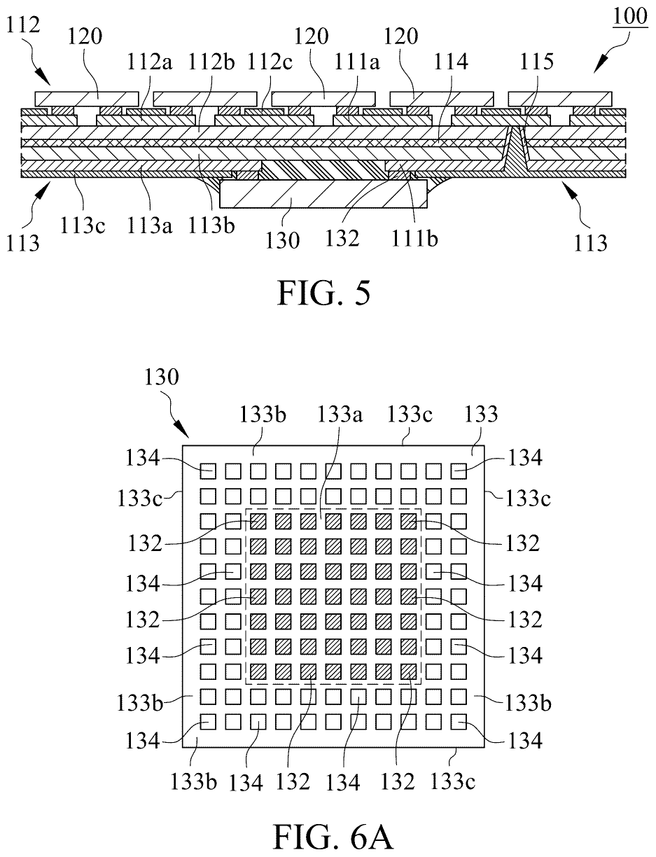

Multiple circuit boards are adhered together to become the carrier 110 in a third embodiment of the present invention. With reference to FIG. 5, the carrier 110 of the third embodiment includes a first circuit board 112, a second circuit board 113, an adhesive layer 114 and a conductive via 115. The first circuit board 112 and the second circuit board 113 are flexible and connected with each other by the adhesive layer 114 to become the carrier 110. The first circuit board 112 includes a first circuit layer 112a, a first substrate 112b and a first protective layer 112c. The first circuit layer 112a is located between the first substrate 112b and the first protective layer 112c and includes the first pads 111a which are not covered by the first protective layer 112c. The second circuit board 113 includes a second circuit layer 113a, a second substrate 113b and a second protective layer 113c. The second circuit layer 113a is located between the second substrate 113b and the second protective layer 113c and includes the second pads 111b which are not covered by the second protective layer 113c. The conductive via 115 is electrically connected to the first circuit layer 112a and the second circuit layer 113a. In the third embodiment, the first pads 111a are provided on the first surface 110b where the outer bending surface 110a1 is located on, and the second pads 111b are provided on the second surface 110c where the inner bending surface 110a2 is located on.

With reference to FIGS. 3 and 4, the chip 130 includes chip pads 131 and bumps 132. Each of the bumps 132 has at least one composite contact 132a including a base 132a1 and a bonding layer 132a2. The bonding layer 132a2 is electrically connected to the chip pad 131 and covers the base 132a1 such that each of the bumps 132 has a nonplanar surface. The base 132a1 can be made of a polymeric material, e.g. polyimide, and it may be a strip or cone, and the shape of the composite contact 132a is changed according to the base 132a1. Preferably, the composite contact 132a further includes a metal layer 132a3 such as under bump metallurgy (UBM). The metal layer 132a3 is located between the base 132a1 and the bonding layer 132a2 and electrically connected to the second pads 111b and the bonding layer 132a2. Referring to FIG. 3, the bumps 132 are bonded to the second pads 111b using the bonding layer 132a2 located on the nonplanar surface such that bonding area of the bumps 132 and the second pads 111b (for example, the area of intermetallic interface between the bonding layer 132a2 and the second pads 111b) can be increased. The increased bonding area can improve bonding strength between the carrier 110 and the chip 130, improve shear stress resistance of the bumps 132 to avoid crack or break generated on the bumps 132 or the intermetallic interface between the bumps 132 and the second pads 111b, and avoid the bumps 132 from peeling from the second pads 111b to cause open circuit.

With reference to FIGS. 3 and 4, preferably, the display panel package 100 further includes a filling material 140 provided between the carrier 110 and the chip 130. Because of the nonplanar surface on the bumps 132, the filling material 140 covers the exposed surface of the bonding layer 132a2 to increase the covered area of the bumps 132 by the filling material 140, thereby improving shear stress resistance of the bumps 132.

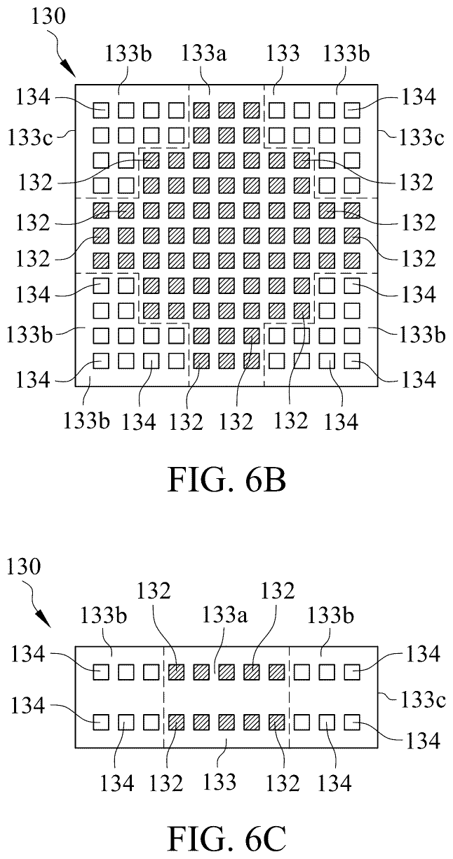

With reference to FIGS. 3 and 6A to 6C, an active surface 133 of the chip 130 has a middle area 133a, an outer area 133b and an edge 133c, and the outer area 133b is located between the middle area 133a and the edge 133c. In the first embodiment, the chip 130 is mounted on the inner bending surface 110a2, the bumps 132 are arranged on the middle area 133a and bonded to the second pads 111b via the nonplanar surface formed on the composite contacts 132a to increase the bonding area of the bumps 132 and the second pads 111b and enhance bonding strength between the carrier 110 and the chip 130. As shown in FIG. 3, a terminal 132a4 of the composite contact 132a can be inserted into the second pad 111b to increase the bonding area of the bumps 132 and the second pads 111b and improve bonding strength between the carrier 110 and the chip 130. Preferably, the chip 130 further includes conductive bumps 134 without composite contact, and the conductive bumps 134 are disposed on the outer area 133b and bonded to the second pads 111b in the first embodiment.

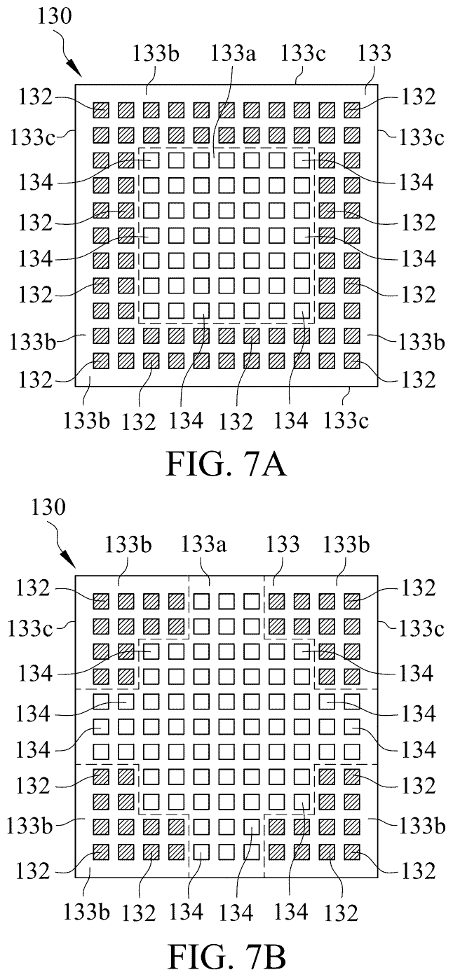

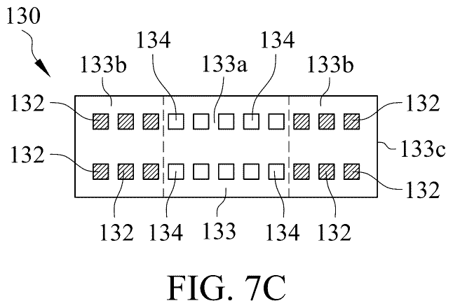

With reference to FIGS. 4 and 7A to 7C, the chip 130 is mounted on the outer bending surface 110a1 and the bumps 132 are disposed on the outer area 133b in the second embodiment. Owing to the bumps 132 are bonded to the second pads 111b through the nonplanar surface of the composite contact 132a, the bonding area of the bumps 132 and the second pads 111b and the bonding strength between the carrier 110 and the chip 130 can be increased. Referring to FIG. 4, the terminal 132a4 of the composite contact 132a can be inserted into the second pad 111b to increase the bonding area of the bumps 132 and the second pads 111b and improve the bonding strength between the carrier 110 and the chip 130. In the second embodiment, the conductive bumps 134 without the composite contact are arranged on the middle area 133a and bonded to the second pads 111b.

While this invention has been particularly illustrated and described in detail with respect to the preferred embodiments thereof, it will be clearly understood by those skilled in the art that is not limited to the specific features shown and described and various modified and changed in form and details may be made without departing from the scope of the claims.

1. A display panel package comprising:
a carrier including a plurality of first pads and a plurality of second pads;
a plurality of light-emitting elements disposed on the carrier and electrically connected to the plurality of first pads; and
at least one chip disposed on a portion to be bent of the carrier and including a plurality of chip pads and a plurality of bumps, each of the plurality of bumps includes at least one composite contact which includes a base and a bonding layer, the bonding layer is electrically connected to one of the plurality of chip pads, the base is covered by the bonding layer such that each of the plurality of bumps has a nonplanar surface, and the bonding layer located on the nonplanar surface is bonded to the plurality of second pads.

2. The display panel package in accordance with claim 1, wherein the portion to be bent of the carrier includes an outer bending surface and an inner bending surface opposite to each other, the at least one chip is mounted on the outer bending surface, an active surface of the at least one chip has a middle area, an outer area and an edge, the outer area is located between the middle area and the edge, and the plurality of bumps are disposed on the outer area.

3. The display panel package in accordance with claim 1, wherein the portion to be bent of the carrier includes an outer bending surface and an inner bending surface opposite to each other, the at least one chip is mounted on the inner bending surface, an active surface of the at least one chip has a middle area, an outer area and an edge, the outer area is located between the middle area and the edge, and the plurality of bumps are disposed on the middle area.

4. The display panel package in accordance with claim 1, wherein the carrier further includes a first circuit board, a second circuit board, an adhesive layer and a conductive via, the first and second circuit boards are connected with each other by the adhesive layer, a first circuit layer of the first circuit board includes the plurality of first pads, a second circuit layer of the second circuit board includes the plurality of second pads, the conductive via is electrically connected to the first and second circuit layers, the plurality of first pads are exposed on a first surface of the carrier where the outer bending surface is located on, and the plurality of second pads are exposed on a second surface of the carrier where the inner bending surface is located on.

5. The display panel package in accordance with claim 2, wherein the carrier further includes a first circuit board, a second circuit board, an adhesive layer and a conductive via, the first and second circuit boards are connected with each other by the adhesive layer, a first circuit layer of the first circuit board includes the plurality of first pads, a second circuit layer of the second circuit board includes the plurality of second pads, the conductive via is electrically connected to the first and second circuit layers, the plurality of first pads are exposed on a first surface of the carrier where the outer bending surface is located on, and the plurality of second pads are exposed on a second surface of the carrier where the inner bending surface is located on.

6. The display panel package in accordance with claim 3, wherein the carrier further includes a first circuit board, a second circuit board, an adhesive layer and a conductive via, the first and second circuit boards are connected with each other by the adhesive layer, a first circuit layer of the first circuit board includes the plurality of first pads, a second circuit layer of the second circuit board includes the plurality of second pads, the conductive via is electrically connected to the first and second circuit layers, the plurality of first pads are exposed on a first surface of the carrier where the outer bending surface is located on, and the plurality of second pads are exposed on a second surface of the carrier where the inner bending surface is located on.

7. The display panel package in accordance with claim 1, wherein the at least one composite contact further includes a metal layer which is located between the base and the bonding layer and electrically connected to the plurality of second pads and the bonding layer.

8. The display panel package in accordance with claim 1, wherein a terminal of the at least one composite contact of each of the plurality of bumps is inserted into the plurality of second pads.

9. The display panel package in accordance with claim 2, wherein the at least one chip further includes a plurality of conductive bumps without a composite contact, the plurality of conductive bumps are disposed on the middle area and bonded to the plurality of second pads.

10. The display panel package in accordance with claim 3, wherein the at least one chip further includes a plurality of conductive bumps without a composite contact, the plurality of conductive bumps are disposed on the outer area and bonded to the plurality of second pads.

11. The display panel package in accordance with claim 1 further comprising a filling material, wherein the filling material is provided between the carrier and the at least one chip to cover an exposed surface of the bonding layer.

12. The display panel package in accordance with claim 1, wherein the at least one composite contact is a strip or a cone.
